(19) United States
(12) Patent Application Publication
(10) Pub. No.: US 2026/0351333 A1
(43) Pub. Date: Nov. 5, 2026

(54) SEMICONDUCTOR PACKAGE WITH REDUNDANT DIE(S) AND METHODS OF MANUFACTURING THE SAME

(71) Applicant: Micron Technology, Inc., Boise, ID (US)

(72) Inventors: Amirul Afiq Bin Hud, Singapore (SG); Chin Hui Chong, Singapore (SG); Soon Sing NG, Singapore (SG); Seng Kim Ye, Singapore (SG); Hong Wan Ng, Singapore (SG); Kelvin Tan Aik Boo, Singapore (SG)

(21) Appl. No.: 19/638,131

(22) Filed: Apr. 3, 2026

Related U.S. Application Data
(60) Provisional application No. 63/797,759, filed on Apr. 30, 2025.

(51) Int. Cl. G11C 29/00; H10B 80/00; H10D 80/30; H10W 90/20; H10W 90/24

(52) U.S. Cl. CPC G11C 29/70; H10B 80/00; H10D 80/30; H10W 90/24; H10W 90/275

(57) ABSTRACT

An apparatus includes one or more replacement dies forming a die stack with a corresponding set of main dies. The one or more replacement dies are configured to replace defects in the main dies after forming the die stack.

### CROSS-REFERENCE TO RELATED APPLICATIONS

The present application claims priority to U.S. Provisional Patent Application No. 63/797,759, filed Apr. 30, 2025, the disclosure of which is incorporated herein by reference in its entirety.

### TECHNICAL FIELD

The present technology is directed to apparatuses, such as semiconductor devices including memory, and several embodiments are directed to semiconductor devices that include one or more redundant dies within device packages.

### BACKGROUND

The current trend in semiconductor fabrication is to manufacture smaller and faster devices with a higher density of components for computers, cell phones, pagers, personal digital assistants, and many other products. Additionally, the device manufacturers are faced with persisting demand for lower prices. Accordingly, circuit designs and components that accommodate the higher density along with the lower costs are ideal. Given such increase in circuit density, increasing manufacturing efficiencies and yield has become even more desirable.

### BRIEF DESCRIPTION OF THE DRAWINGS

FIG. 1A is a side view of a first package.

FIG. 1B is a side view of a second package.

FIG. 1C is an illustration of a group wiring scheme.

FIG. 1D is an illustration of a die selection scheme.

FIG. 2 is a side view of a first package having a redundant die in accordance with embodiments of the technology.

FIG. 3 is a side view of a second package having a redundant die in accordance with embodiments of the technology.

FIG. 4 is an illustration of a third package having a set of redundant dies in accordance with embodiments of the technology.

FIG. 5A is an illustration of a group wiring scheme for packages including a redundant die in accordance with embodiments of the technology.

FIG. 5B is an illustration of a die selection scheme for packages including a redundant die in accordance with embodiments of the technology.

FIG. 6 is a block diagram of a first example memory in accordance with embodiments of the technology.

FIG. 7 is a block diagram of a computing system having a second example memory in accordance with embodiments of the technology.

FIG. 8 is a flow diagram illustrating an example method of manufacturing an apparatus in accordance with an embodiment of the present technology.

FIG. 9 is a schematic view of a system that includes an apparatus configured in accordance with embodiments of the present technology.

### DETAILED DESCRIPTION

In the following description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with semiconductor devices are not shown, or are not described in detail, to avoid obscuring other aspects of the technology. In general, it should be understood that various other devices, systems, and methods in addition to those specific embodiments disclosed herein may be within the scope of the present technology.

Several embodiments of semiconductor devices, packages, and/or assemblies in accordance with the present technology can include a set or a stack of memory dies, and the stack can include one or more redundant dies. Each of the memory dies can include memory cells, such as Dynamic Random Access Memory (DRAM) cells or persistent memory cells (e.g., Flash NAND memory cells). Each of the dies can further include redundant memory cells (e.g., redundant memory blocks) that are configured to replace other memory cells. For example, each memory die can have a targeted die capacity, and the corresponding package including the set of memory dies can have a targeted package capacity. Accordingly, each die can have the targeted number of memory cells or blocks that correspond to the targeted die capacity.

However, manufacturing processes may cause defects in the targeted set of memory cells. In accounting for the potential manufacturing defects in the targeted set, each of the dies can have redundant memory cells/blocks configured to replace the targeted set. To account for further defects, such as additional defects that occur during subsequent processing (e.g., die stacking/mounting and/or other package manufacturing processes), embodiments of the current technology can have redundant dies in the package. The memory cells in the redundant dies can provide additional replacement cells/blocks that can be used to replace defective memory cells/blocks within one or more of the other dies within the package.

As an illustrative example, a four-die package having four targeted memory dies can include one or two redundant dies. For example, when the memory dies can each communicate over multiple channels and/or entire data unit (e.g., for NAND memory cells), the package can include one redundant die. Otherwise, when the memory dies can each communicate with limited number of channels, such as half the channels, or communicate a portion of the data unit (e.g., an upper BYTE or a lower BYTE for DRAM architecture), the package can include a redundant die for each channel grouping/portion. Similarly, a 16-die package can include one redundant die for a total of 17 dies or two redundant dies for a total of 18 dies. In some embodiments, the 16-die package can include four stacks of four dies, with each stack supporting two different data groupings, such as for the DRAM architecture; each stack can include two redundant dies (e.g., one for each data grouping) to bring the total number of dies in the package to 24.

To communicate with the redundant die, the redundant die (along with any target dies having the same design) can include a redundant die selection pin. The redundant die selection pin can be used along with a chip enable pin that identifies the individual target dies. The redundant die can share the chip enable pin connection with one of the target dies and further receive the redundant die selection signal through the corresponding pad.

The memory packages having the redundant die(s) can provide increased yield rates. The redundant dies can provide the number of valid blocks (NVB) required by downstream customers, such as for enterprise applications. Further, the redundant dies can provide overall relief for replacement blocks as the number of memory dies within in a package increases. For example, as the number of stacked memory dies increases within a package, the likelihood of one such die having insufficient local redundant blocks increases. Likewise, with the increased number of dies in the stack, the impact of the one bad die is increased. Thus, having redundant dies that provide replacement memory cells/blocks in addition to the replacement blocks local to each die provides the flexibility to maintain the use of the die stacks having the die with insufficient local replacement cells.

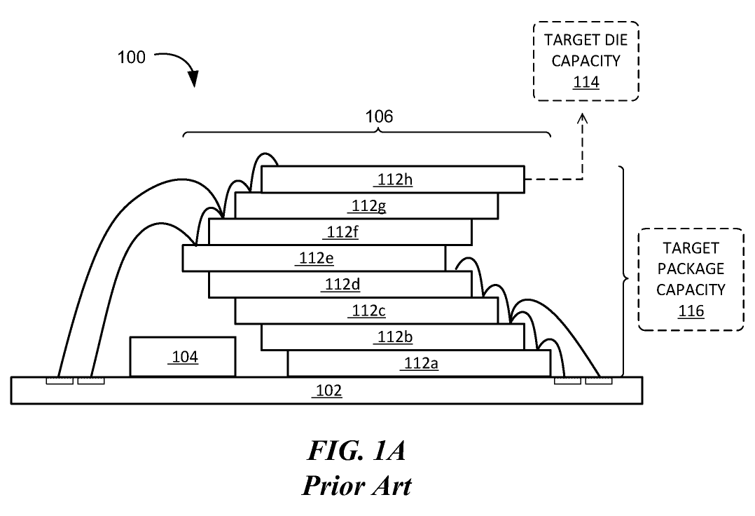

For context, conventional packages are limited to local replacement cells and thus include only the number of dies necessary for the targeted capacity for the corresponding package. As an example, FIG. 1A is a side view of a first package 100 (also referred to as the “package 100”). The package 100 includes a package substrate 102 having an interfacing control circuit 104 (e.g., a logic, such as a memory controller or an input/output element (IOE)) and a die stack 106 mounted thereon. The die stack 106 includes a targeted number of dies 112 that each have a targeted die capacity 114 for providing a targeted package capacity 116. For the illustrated example, the die stack 106 includes eight memory dies 112a – 112h, and each of the dies 112a – 112h has the targeted die capacity 114 (e.g., 256 Megabits per die, 1 Gigabits per die, etc.). When the package 100 includes the same type of dies, the targeted package capacity 116 for the package 100 is a product of (1) the designated storage capacity per die and (2) the total number of such dies within the package 100. For example, when each of the dies 112a – 112h has the targeted die capacity 114 of 1 Gigabits for storage, the package 100 having eight such dies can have the targeted package capacity 116 of 8 Gigabits.

For illustrative purposes, the die stack 106 is illustrated using eight dies. However, it is understood that the stacking configuration may include a different number of dies, such as 16, 24, 32, and so forth. The corresponding targeted package capacity 116 can vary according to the number of dies.

Continuing with the illustrated example, the memory dies 112a – 112h are coupled to the interfacing control circuit 104 through connections (e.g., traces, vias, etc.; not shown) within or on the substrate 102, pads on the substrate and the memory dies 112a – 112h, and interconnects, such as bondwires. In some embodiments, the memory dies 112a – 112h are grouped according to function or operational architecture (e.g., shared memory channels), physical connections (e.g., common connections and/or substrate pad connections), or a combination thereof. For example, one set of memory dies (e.g., dies 112a – 112d) corresponds to one or more memory channels, and a different set of memory dies (e.g., dies 112e – 112h) corresponds to one or more different memory channels. Moreover, the memory dies 112a – 112h may be tiled, such as by offsetting and overhanging a die attached over a supporting die. For the illustrated example, the memory dies (e.g., dies belonging to the same functional grouping, such as the memory dies 112a – 112d as shown) in one group are tiled and offset along one or more lateral directions, and the memory dies (e.g., the memory dies 112e – 112h) for a different group are tiled and offset along a different or an opposite lateral direction(s). For the illustrated embodiment, the two different tiled set of dies can be attached on top of each other.

For further context, FIG. 1B is a side view of a second package 150 (also referred to as the “package 150”). The package 150 is similar to the package 100 with a different stacking configuration. For example, the package 150 includes a package substrate 152 having an interfacing control circuit 154 and a set 156 of dies 162 mounted thereon. The die set 156 includes a targeted number of dies 162 (e.g., eight dies 162a – 162h). The dies 162 are coupled to the interfacing control circuit 154 using connections on or internal to the substrate 152 (e.g., traces, vias, and the like) and interconnections (e.g., bondwires) that connect dies to each other and/or the internal substrate connections.

Illustrating a different stacking configuration from the package 100, the package 150 further includes a first die stack 156a and a second die stack 156b. Each of the die stacks 156a and 156b includes a number of dies (e.g., four) that are tiled and offset along one or more lateral directions. For example, the first die stack 156a may correspond to memory dies sharing a common memory channel, one or more common inter-die connections, and/or one or more common substrate pad connections. Likewise, the second die stack 156b may correspond to memory dies sharing a common memory channel, one or more common inter-die connections, and/or one or more common substrate pad connections different from that/those for the first die stack 156a. Regarding the tiling configuration, the die stacks die stack 156a and 156b can be offset toward each other and/or toward the interfacing control circuit 154. One or more of the dies may overlap the interfacing control circuit 154.

The package 150 includes a targeted number of dies 162 (e.g., eight dies 162a – 162h) that each have a targeted die capacity 164 for providing a targeted package capacity 166 overall. When the total number of dies and the targeted die capacity 164 for each of the dies 162 matches those of the package 100, the targeted package capacity 166 is the targeted package capacity 116 of FIG. 1A, regardless of the stacking configuration. As mentioned above, it is understood that the die stacks 156a and 156b may have a different number of dies, such as eight, 16, 32, and so forth.

To illustrate the connection schemes, FIG. 1C is an illustration of a group wiring scheme 160. The group wiring scheme 160 has corresponding pins or pads (e.g., a matching pad based on location, designation, internal connections, etc.) on the dies within one grouping connected together. For example, the dies 112a – 112d of FIG. 1A can have the corresponding pins connected together as one node per the group wiring scheme 160, and the dies 112e – 112h of FIG. 1A can have the corresponding pins connected together for the package 100. Also, the dies 162a – 162d of FIG. 1B can have the corresponding pins that are connected together per the group wiring scheme 160, and the dies 162e – 162h of FIG. 1B can have corresponding pins connected together per the group wiring scheme 160.

The packages 100 and 150 can have a die selection mechanism along with the shared group wiring scheme 160. FIG. 1D is an illustration of a die selection scheme 170. For the die selection scheme 170, each die within the grouping (e.g., the set of dies connected according to the group wiring scheme 160) can have a selection connection 172 (e.g., a pin, a pad, or the like) that receives a corresponding signal from the interfacing control circuit (e.g., circuit 104 of FIG. 1A or 154 of FIG. 1B). The selection connection 172 of each die can be uniquely coupled to the control circuit that sends the corresponding selection signal to a die selected to send or receive data. Accordingly, the dies can be configured to receive or send signals on its pins/pads when the selection signal is detected/received through the selection connection 172. Otherwise, given the die-grouping wiring scheme 160 having shared connections, the dies can be configured to ignore the signals received on its pins/pads without the selection signal.

As described above, each of the dies 112 of FIG. 1A and 165 of FIG. 1B may include manufacturing defects that take away from its capacity. Accordingly, each of the dies 112 and 165 may be manufactured with additional circuitry (e.g., redundant memory) that exceed the targeted die capacity 114. Each of the dies 112 and 165 are tested for the defects at the end of the manufacturing process. When the defects are detected, the additional circuitry can be configured or set to replace the defective circuits in an effort to maintain the targeted die capacity 114 in view of the manufacturing defects.

Once the packages 100 and 150 are assembled, the functionalities of the package and the individual dies within may be tested again. However, such tests may discover defects that were previously undetected at the die level or defects that formed during subsequent manufacturing or assembly processes (e.g., stacking, subsequent package testing, etc.). At this point, the adjustments for replacing the defective circuits (e.g., memory cells/blocks) with replacement circuits local to the die may be unavailable after the assembly. Also, the problematic die(s) may not have sufficient local replacement circuits. As a result, the corresponding package would be unable to meet the targeted package capacity, and the entire assembly may be rendered unusable. Such failure scenario causes the loss of time and the resources used to manufacture the failing package, and even the valid dies within the failing package.

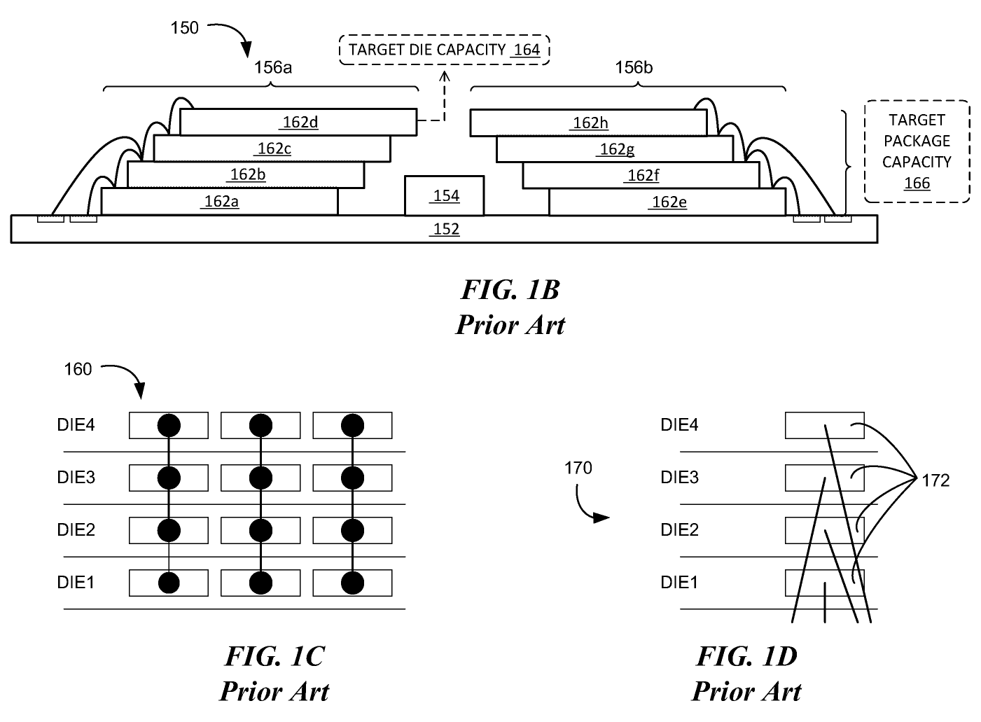

In contrast, embodiments of the present technology include one more redundant dies (e.g., memory dies) in the package. The circuitry in the redundant dies can be used to replace defects within dies that cannot be addressed using the replacement circuits within the same defective die. As an example, FIG. 2 is a side view of a first package 200 (also referred to as the “package 200”) having a redundant die 220 in accordance with embodiments of the technology.

The package 200 can include a package substrate 202 having an interfacing control circuit 204 (e.g., a logic, such as a memory controller or an input/output element (IOE)) and a die stack 206 mounted thereon. In some embodiments, the package 200 can include a memory device, such as a Flash NAND storage device or a DRAM storage device. Moreover, the package 200 can correspond to an enterprise component, a device with high speed capability, and/or the like.

The die stack 206 can include a targeted number of main dies 212 that each have a targeted die capacity 214 for providing a targeted package capacity 216 overall for the package 200. For the illustrated example, the die stack 206 can includes eight main dies 212a – 212h, and each of the main dies 212a – 212h can have the targeted die capacity 214 (e.g., 256 Megabits per die, 2 Gigabits per die, etc.). When the package 200 includes the same type of dies, the targeted package capacity 216 for the package 200 can be a product of (1) the designated storage capacity per main die and (2) the total number of such main dies within the package 200. For example, when each of the main dies 212a – 212h has the targeted die capacity 214 of 1 Gigabits for storage, the package 200 having eight such dies can have the targeted package capacity 216 of 8 Gigabits.

Continuing with the illustrated example, the main dies 212a – 212h can be coupled to the interfacing control circuit 204 through connections (e.g., traces, vias, etc.; not shown) within or on the substrate 202, pads on the substrate and the main dies 212a – 212h, and interconnects, such as bondwires. In some embodiments, the main dies 212a – 212h can be grouped according to function or operational architecture (e.g., shared memory channels), physical connections (e.g., common connections and/or substrate pad connections), or a combination thereof. For example, one set of memory dies (e.g., the main dies 212a – 212d) can correspond to one or more memory channels, and a different set of memory dies (e.g., the main dies 212e – 212h) can correspond to one or more different memory channels.

Moreover, the main dies 212a – 212h may be tiled, such as by offsetting and overhanging a die attached over a supporting die. For the illustrated example, the memory dies (e.g., dies belonging to the same functional grouping, such as the main dies 212a – 212d as shown) in one group can be tiled and offset along one or more lateral directions, and the memory dies (e.g., the main dies 212e – 212h) for a different group can be tiled and offset along a different or an opposite lateral direction(s). For the illustrated embodiment, the two different tiled sets of dies can be attached on top of each other.

In addition to the main dies 212, the package 200 can include one or more of the replacement dies 220. The replacement dies 220 can each include circuitry that is commonly included in the main dies 212. In some embodiments, the replacement dies 220 and the main dies 212 can have same matching circuitry and design but have different purposes or designations. For example, the main dies 212 can be designated to first fill the overall target package capacity 216, and the replacement dies 220 can be designated for replacing defective circuitry in the main dies 212. When defects are discovered within the main dies 212 after the package assembly and local replacement circuits (e.g., redundant memory) within the same defect-having die is unavailable, the functional circuitry of the replacement dies 220 can be used to replace the defects. Thus, for the overall package 200, the replacement dies 220 can be used to offset the defects in the main dies 212 and maintain the targeted package capacity 116. Stated differently, when one or more of the main dies 212 fail to provide the targeted die capacity 214, the functional circuitry (e.g., memory cells/blocks) of the replacement dies 220 can be used to make up the deficiencies of such dies.

As per the manufacturing and assembly processes described above, the package 200 and the main dies 212 therein can be tested for defects after the assembly process. When defects are discovered in the main dies 212 and the local replacement circuits are unavailable, available circuits in the replacement die 220 can be identified as replacements for the defects. The corresponding replacement scheme, such as mapping for the addresses of the defective circuit on one of the main dies 212 to a replacement circuit on the replacement die 220, can be stored in the interfacing control circuit 204. For example, the interfacing control circuit 204 can have a replacement selection circuit 224 including persistent memory (e.g., fuses) storing the replacement mapping, a logic circuit configured to identify an address (e.g., a virtual address or a physical address) corresponding to the defective circuit and the corresponding replacement circuit. The replacement selection circuit 224 can be configured to access the replacement circuit in the replacement die 220 instead of defective circuit in the corresponding main die 212 according to the output of its replacement logic circuit.

For illustrative purposes, the die stack 206 is illustrated using eight main dies and one replacement die. However, it is understood that the stacking configuration may include a different number of dies, such as 16, 24, 32, and so forth for the main dies and two or more for the replacement dies. The corresponding targeted package capacity 216 and the replacement capacity can vary according to the number of dies. For example, the die stack 206 can include one or more replacement dies for each a main die grouping. Some other examples of the package 200 can include 16, 20, 24, 28, 32, or other number of main dies with one or two replacement dies. Moreover, in some embodiments, the package 200 can include multiple (e.g., two or more) interfacing control circuits.

Further, the die stack 206 is shown with the replacement die 220 located in a middle portion and on top of the first die grouping. Such placement of the replacement die 220 at a middle portion of the die stack 206 can provide sufficient redundant memory/storage cells across the upper and lower portions of the stack. However, it is further understood that the replacement die(s) 220 can be located differently, such as directly on the substrate 202 as the lowest/first die in the grouping, at the middle portion of a grouping (e.g., a cascaded or a shingled grouping, such as dies 212a-d as one grouping and dies 212e-h as another grouping), or at the top of the die stack 206. The replacement die 220 located at a middle portion of a grouping can similarly provide sufficient redundant memory/storage cells across the upper and lower portions of the grouping.

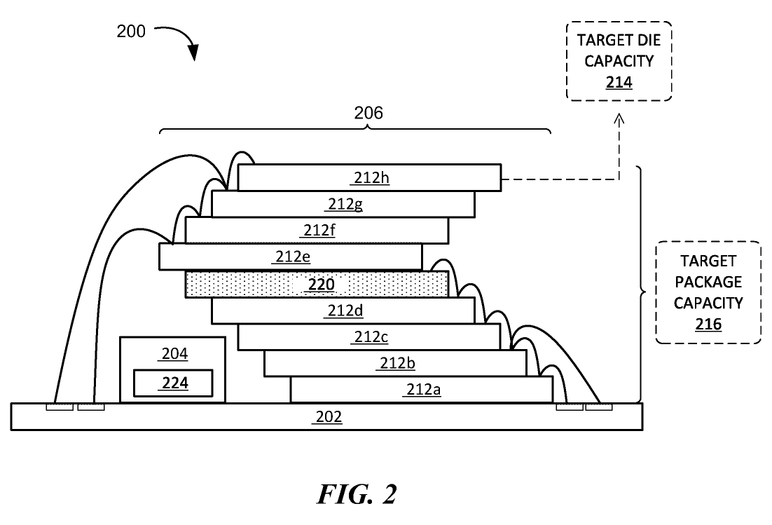

As a further example, FIG. 3 is a side view of a second package 300 (also referred to as the “package 300”) having a redundant die 320 in accordance with embodiments of the technology. The package 300 can include a package substrate 302 having an interfacing control circuit 304 (e.g., a logic, such as a memory controller or an input/output element (IOE)) and a set 306 of dies mounted thereon. In some embodiments, the package 300 can include a memory device, such as a Flash NAND storage device or a DRAM storage device. Moreover, the package 300 can correspond to an enterprise component, a device with high speed capability, and/or the like.

The die set 306 can include a targeted number of main dies 312 that each have a targeted die capacity 314 for providing a targeted package capacity 316 overall for the package 300. For the illustrated example, the die set 306 (e.g., the die stack) can includes eight main dies 312a – 312h, and each of the main dies 312a – 312h can have the targeted die capacity 314 (e.g., 356 Megabits per die, 3 Gigabits per die, etc.). When the package 300 includes the same type of dies, the targeted package capacity 316 for the package 300 can be a product of (1) the designated storage capacity per main die and (2) the total number of such main dies within the package 300. For example, when each of the main dies 312a – 312h has the targeted die capacity 314 of 1 Gigabits for storage, the package 300 having eight such dies can have the targeted package capacity 316 of 8 Gigabits.

Continuing with the illustrated example, the main dies 312a – 312h can be coupled to the interfacing control circuit 304 through connections (e.g., traces, vias, etc.; not shown) within or on the substrate 302, pads on the substrate and the main dies 312a – 312h, and interconnects, such as bondwires. In some embodiments, the main dies 312a – 312h can be grouped according to function or operational architecture (e.g., shared memory channels), physical connections (e.g., common connections and/or substrate pad connections), stack configurations, or a combination thereof. For example, one set of memory dies (e.g., the main dies 312a – 312d) can be stacked on top of each other to form a first die stack 306a, and another set of memory dies (the main dies 312e – 312h) can be stacked on top of each other to form a second die stack 306b. Additionally, or alternatively, the groupings of the memory dies (e.g., the first die stack 306a and the second die stack 306b) can each correspond to one or more memory channels.

Returning to the die stacks 306a and 306b, the main dies therein may be tiled, such as by offsetting and overhanging a die attached over a supporting die. For the illustrated example, the memory dies in the first die stack 306a can tiled and offset along one or more lateral directions, and the memory dies in the second die stack 306b can be tiled and offset along a different or an opposite lateral direction(s). For the illustrated embodiment, the two different tiled set of dies can be offset toward each other, and/or one or more dies therein can overlap with the interfacing control circuit 304.

In addition to the main dies 312, the package 300 can include one or more of the replacement dies 320, such as in the first die stack 306a, the second die stack 306b, or both. The replacement dies 320 can each include circuitry that is commonly included in the main dies 312. In some embodiments, the replacement dies 320 and the main dies 312 can have same matching circuitry and design but have different purposes or designations. For example, the main dies 312 can be designated to first fill the overall target package capacity 316, and the replacement dies 320 can be designated for replacing defective circuitry in the main dies 312. When defects are discovered within the main dies 312 after the package assembly and local replacement circuits (e.g., redundant memory) within the same defect-having die is unavailable, the functional circuitry of the replacement dies 320 can be used to replace the defects. Thus, for the overall package 300, the replacement dies 320 can be used to offset the defects in the main dies 312 and maintain the targeted package capacity 116. Stated differently, when one or more of the main dies 312 fail to provide the targeted die capacity 314, the functional circuitry (e.g., memory cells/blocks) of the replacement dies 320 can be used to make up the deficiencies of such dies.

As per the manufacturing and assembly processes described above, the package 300 and the main dies 312 therein can be tested for defects after the assembly process. When defects are discovered in the main dies 312 and the local replacement circuits are unavailable, available circuits in the replacement die 320 can be identified as replacements for the defects. The corresponding replacement scheme, such as mapping for the addresses of the defective circuit on one of the main dies 312 to a replacement circuit on the replacement die 320, can be stored in the interfacing control circuit 304. For example, the interfacing control circuit 304 can have a replacement selection circuit 324 including persistent memory (e.g., fuses) storing the replacement mapping, a logic circuit configured to identify an address (e.g., a virtual address or a physical address) corresponding to the defective circuit and the corresponding replacement circuit. The replacement selection circuit 324 can be configured to access the replacement circuit in the replacement die 320 instead of defective circuit in the corresponding main die 312 according to the output of its replacement logic circuit.

For illustrative purposes, the die stacks 306a and 306b are each illustrated using four main dies and one replacement die in the first die stack 306a. However, it is understood that the stacking configuration may include a different number of dies, such as 8, 16, 34, 32, and so forth for the main dies and two or more for the replacement dies. The corresponding targeted package capacity 316 and the replacement capacity can vary according to the number of dies. For example, the die set 306 can include one or more replacement dies for each a main die grouping. Some other examples of the package 300 can include 16, 30, 34, 38, 32, or other number of main dies with one or two replacement dies. Moreover, in some embodiments, the package 300 can include multiple (e.g., two or more) interfacing control circuits.

Further, the die set 306 is shown with the replacement die 320 located top of the first die stack 306a. However, it is further understood that the replacement die(s) 320 can be located differently, such as directly on the substrate 302 or as the lowest/first die in the grouping, or at the middle portion of the die stack (e.g., at a middle portion of the cascaded/shingled stack). The replacement die 320 located at a middle portion of the die stack can provide sufficient redundant memory/storage cells across the upper and lower portions of the stack. Moreover, the package 300 can include one or more replacement dies 320 on each of the die stacks 306a and 306b, at matching locations or differing locations for the first and second die stacks 306a and 306b.

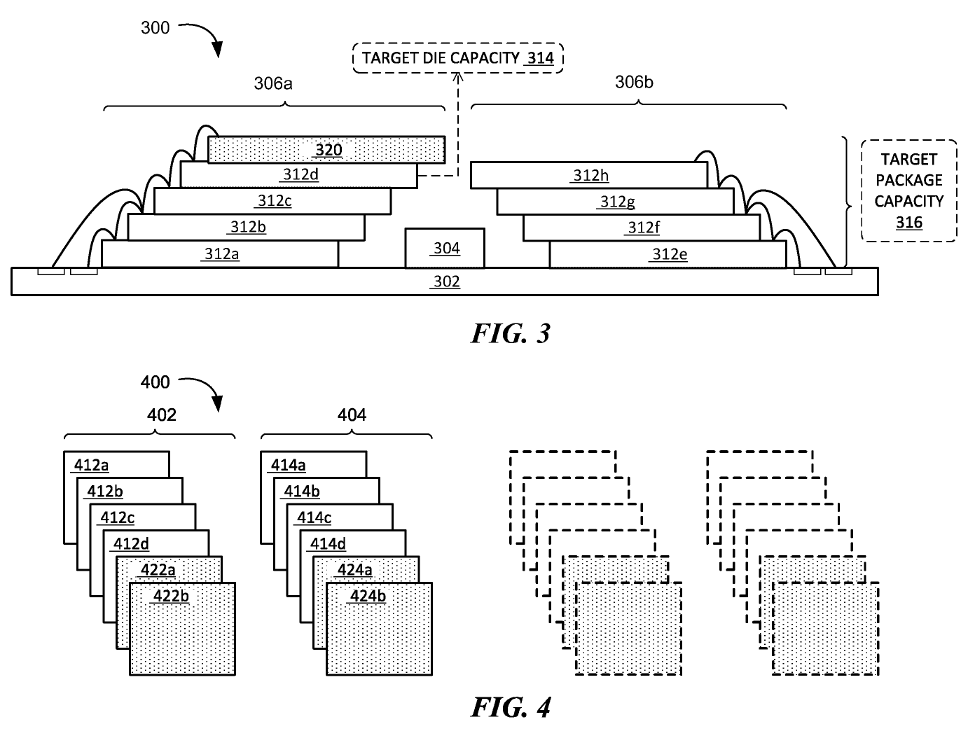

FIG. 4 is an illustration of a third package 400 having a set of redundant dies in accordance with embodiments of the technology. Like the packages 200 of FIG. 2 and/or 300 of FIG. 3, the third package 400 can include a memory device, such as a Flash NAND device, a DRAM storage device, an enterprise component, a device with high speed capability, or a combination thereof. Moreover, while not shown in FIG. 4, the package 400 can include a package substrate, an interfacing control circuit, or a combination thereof. The package substrate can include internal electrical connections that couple main dies to the interfacing control circuit, a separate memory controller, or a combination thereof.

The package 400 can include the main dies (e.g., memory dies, such as dies having NAND storage cells or DRAM storage cells) arranged into groupings, such as according to functional capabilities, physical groupings, electrical connections, or a combination thereof. For the example illustrated in FIG. 4, the package 400 can include (1) a first die grouping 402 having main dies 412a – 412d and (2) a second die grouping 404 having main dies 414a – 414d. Each die grouping 402/404 can correspond to a die stack, correspond to one or more commonly shared memory channels, portions of a data unit, or a combination thereof. In some embodiments, such as for DRAM dies, each of the die groupings 402 and 404 can correspond to a die stack having dies/circuits therein configured to store and provide access to upper bytes and lower bytes for a shared channel(s). As an illustrative example, the dies 412a and 412b can be coupled to one channel and/or be configured for storing a lower bytes of stored data units. Also, the dies 412c and 412d can be coupled to a different channel and/or be configured for storing upper bytes of stored data units.

Each of the die groupings can include multiple redundant dies, one or more for each subgrouping within the die grouping. For example, the first die grouping 402 can include redundant dies 422a and 422b. The redundant die 422a can include functional circuitry, such as memory cells/blocks, configured to replace the functional circuitry of a first subgrouping (e.g., the memory dies 412a and 412b), and the redundant die 422b can similarly correspond to a second subgrouping (e.g., the memory dies 412c and 412d). Likewise, the second die grouping 404 can include redundant dies 424a and 424b that are each configured to provide replacement circuitry for subgroupings of dies. For example, the replacement die 424a can be coupled to the same channel or data portion as the main dies 414a and 414b and provide replacement for circuits thereto, and the replacement die 424b can be coupled to the same channel or data portion as the main dies 414c and 414d and provide replacement for circuits thereto.

As described above, the replacement dies 422 and 424 can provide replacement circuits for maintaining a target package capacity for the package 400. The circuits within the replacement dies 422 and 424 can be provided as replacements when one or more of the main dies 412 and 414 within the corresponding groupings are unable to meet a targeted die capacity.

For illustrative purposes, the package 400 is shown having two die stacks that each have four main dies and two replacement dies. However, it is understood that the package 400 can be configured differently. For example, the package 400 can have four die stacks, with the two additional die stacks shown using dashed lines, or more (e.g., 8, 12, 16, or more groupings). Thus, for the four stack example with each stack including two subgroupings and one replacement die for each subgrouping, the package 400 can include a total of 24 dies (16 main dies and 8 replacement dies) to support the total package capacity corresponding to the 16 main dies.

Moreover, the package 400 can have more than three or more subgroupings within each grouping/stack, two or more replacement dies for each subgrouping, or a combination thereof. Also, the replacement dies can be located at different positions within the subgrouping/stack, such as at the bottom position, separated from each other and attached relative to each supported subgrouping, etc.

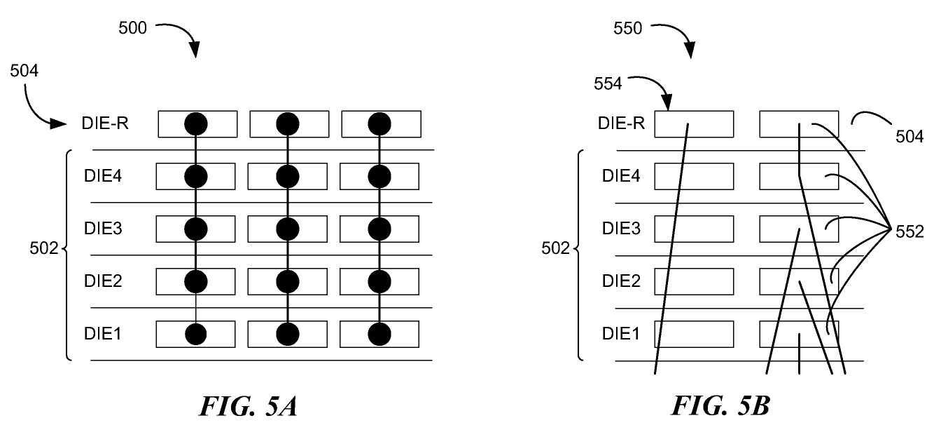

FIG. 5A is an illustration of a group wiring scheme 500 for packages including a redundant die in accordance with embodiments of the technology. The group wiring scheme 500 can include commonly tying or connecting corresponding pads/pins across the dies within each subgrouping or stacks, across the main dies and replacement die, in the package. For example, the group wiring scheme 500 can correspond to connecting the corresponding or matching pins/pads of main dies 502 and a redundant die 504.

The group wiring scheme 500 can be applied to the package 200 of FIG. 2, the package 300 of FIG. 3, and/or the package 400 of FIG. 4. With reference to the examples illustrated in FIGS. 2-4, the group wiring scheme 500 can correspond to wiring schemes for the first subgrouping (e.g., dies 212a – 212d of FIG. 2) for the package 200, the first die stack 306a of FIG. 3, the first die grouping 402 or a portion thereof, etc. The main dies 502 can correspond to the dies 212a – 212d of FIG. 2, the main dies 312a – 312d of FIG. 3, and the main dies 412a and 412b. The replacement die 504 can correspond to the replacement die 220 of FIG. 2, the replacement die 320 of FIG. 3, and the replacement die 422a.

FIG. 5B is an illustration of a die selection scheme 550 for packages including a redundant die in accordance with embodiments of the technology. The die selection scheme 550 can correspond to a mechanism for selecting one/each die as a communication target within the subgrouping/stack. For the die selection scheme 550 each die within the grouping (e.g., the set of dies connected according to the group wiring scheme 500 of FIG. 5A) can have a die-select connection 552 (e.g., a pin, a pad, or the like) that receives a corresponding signal from the interfacing control circuit (e.g., circuit 204 of FIGS. 2, 304 of FIG. 3, and/or the like). The die-select connection 552 of each main die can be uniquely coupled to the control circuit that sends the corresponding die-select signal to a die selected to send or receive data. Accordingly, the dies can be configured to receive or send signals on its pins/pads when the die-select signal is detected/received through the die-select connection 552. Otherwise, given the grouping wiring scheme 500 having shared connections, the dies can be configured to ignore the signals received on its pins/pads without the die-select signal.

The redundant die 504 for the grouping can share the die-select connection 552 with one of the main dies 502 (e.g., die 4 in the grouping/stack). In other words, the die-select signal for DIE4 can further be received at the replacement die 504. To distinguish between the dies that share the die-select connection 552, the main dies 502 and the redundant die 504 can each include a redundant-select connection 554 (e.g., a pin, a pad, or the like) that receives a corresponding signal from the interfacing control circuit. Within the die grouping, the redundant die 504 can have the redundant-select connection 554 thereon connected to the interfacing control circuit, and the remainder of the main dies 502 can have their local redundant-select connections 554 unconnected.

During operation, to access the redundant die 504, the interfacing control circuit can generate and send a redundant-select signal through the redundant-select connection 554 of the redundant die 504. In response, when the redundant-select signal and the die-select signal (e.g., DIE4 selection for example shown in FIG. 5B) are received at the redundant die 504, the redundant die 504 can communicate through the group wiring scheme 500 and/or perform the corresponding function. For example, the interfacing control circuit send a command, an address, a data (e.g., DQ communication), and/or the like over shared connection/node for the group wiring scheme 500. To target the redundant die 504 (e.g., during qualification or testing), the interfacing control circuit can send both the redundant-select signal and the die-select signal through corresponding die-select connection 552 and the redundant-select connection 554. In response to the select signals, the redundant die 504 can receive the command, the address, the data, etc. from the interfacing control circuit and perform the corresponding operation. In some embodiments, the redundant die 504 can send information, such as accessed/read data (e.g., DQ communication), status reports, acknowledgements, and/or the like, when the redundant-select signal and the die-select signal are active.

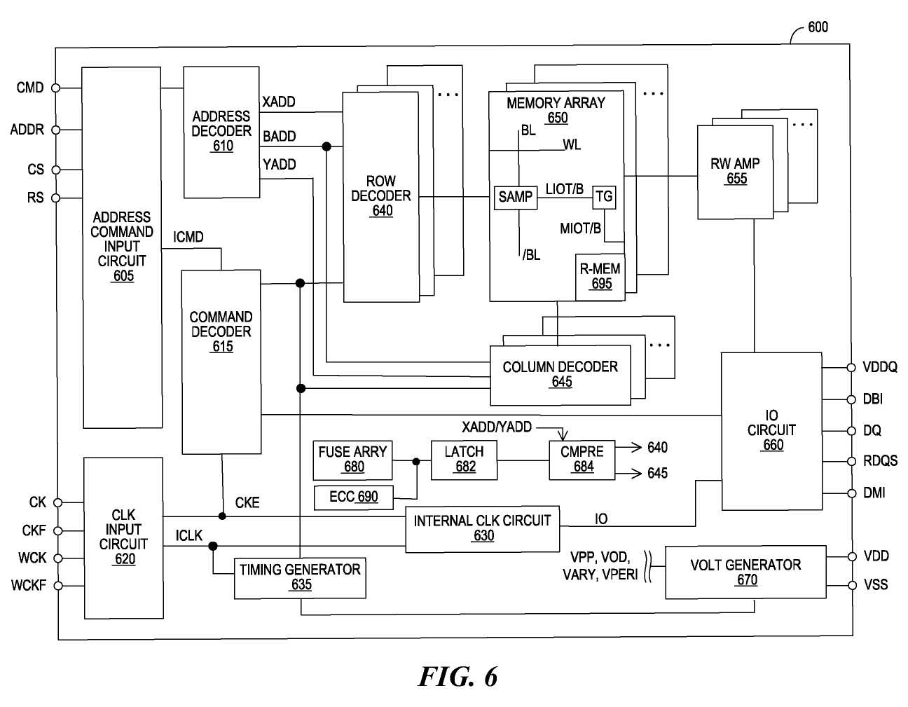

In some embodiments, the packages 200 of FIGS. 2, 300 of FIG. 3, and/or 400 of FIG. 4 can include memory devices. Illustrating an example of the memory devices, FIG. 6 is a block diagram of an apparatus 600 (e.g., a semiconductor die assembly, including a three-dimensional integration (3DI) device or a die-stacked package) in accordance with an embodiment of the present technology. For example, the apparatus 600 can include a DRAM or a portion thereof that includes one or more dies/chips.

The apparatus 600 may include an array of memory cells, such as memory array 650. The memory array 650 may include a plurality of banks (e.g., banks 0–15), and each bank may include a plurality of word-lines (WL), a plurality of bit lines (BL), and a plurality of memory cells arranged at intersections of the word-lines and the bit lines. Memory cells can include any one of a number of different memory media types, including capacitive, magnetoresistive, ferroelectric, phase change, or the like. The selection of a word-line WL may be performed by a row decoder 640, and the selection of a bit line BL may be performed by a column decoder 645. Sense amplifiers (SAMP) may be provided for corresponding bit lines BL and connected to at least one respective local I/O line pair (LIOT/B), which may in turn be coupled to at least respective one main I/O line pair (MIOT/B), via transfer gates (TG), which can function as switches. The sense amplifiers and transfer gates may be operated based on control signals from decoder circuitry, which may include the command decoder 615, the row decoders 640, the column decoders 645, any control circuitry of the memory array 650, or any combination thereof. The memory array 650 may also include plate lines and corresponding circuitry for managing their operation.

The apparatus 600 may employ a plurality of external terminals that include command and address terminals coupled to a command bus and an address bus to receive command signals (CMD) and address signals (ADDR), respectively. The apparatus 600 may further include a chip select terminal to receive a chip select signal (CS), clock terminals to receive clock signals CK and CKF, data clock terminals to receive data clock signals WCK and WCKF, data terminals DQ, RDQS, DBI, and DMI, power supply terminals VDD, VSS, and VDDQ. In some embodiments, the chip select signal (CS) can correspond to the die-select signal received through the die-select connection 552 of FIG. 5B. Additionally, the apparatus 600 may include a redundant select terminal (e.g., the redundant-select connection 554 of FIG. 5B) for receiving the redundant-select signal.

The command terminals and address terminals may be supplied with an address signal and a bank address signal (not shown in FIG. 6) from outside. The address signal and the bank address signal supplied to the address terminals can be transferred, via a command/address input circuit 605, to an address decoder 610. The address decoder 610 can receive the address signals and supply a decoded row address signal (XADD) to the row decoder 640, and a decoded column address signal (YADD) to the column decoder 645. The address decoder 610 can also receive the bank address signal and supply the bank address signal to both the row decoder 640 and the column decoder 645.

The command and address terminals may be supplied with command signals (CMD), address signals (ADDR), chip select signals (CS), redundant-select signal (RS), or a combination thereof from a memory controller or a package-local interfacing control circuit. The command signals may represent various memory commands from the memory controller (e.g., including access commands, which can include read commands and write commands). The chip select signal (CS) and/or the redundant-select signal (RS) may be used to select the apparatus 600 to respond to commands and addresses provided to the command and address terminals. When an active chip select signal (CS) and/or an active redundant-select signal (RS) is provided to the apparatus 600, the commands and addresses can be decoded, and memory operations can be performed. The command signals may be provided as internal command signals ICMD to a command decoder 615 via the command/address input circuit 605. The command decoder 615 may include circuits to decode the internal command signals ICMD to generate various internal signals and commands for performing memory operations, for example, a row command signal to select a word-line and a column command signal to select a bit line. The command decoder 615 may further include one or more registers for tracking various counts or values (e.g., counts of refresh commands received by the apparatus 600 or self-refresh operations performed by the apparatus 600).

Read data can be read from memory cells in the memory array 650 designated by row address (e.g., address provided with an active command) and column address (e.g., address provided with the read). The read command may be received by the command decoder 615, which can provide internal commands to input/output circuit 660 so that read data can be output from the data terminals DQ, RDQS, DBI, and DMI via read/write amplifiers 655 and the input/output circuit 660 according to the RDQS clock signals. The read data may be provided at a time defined by read latency information RL that can be programmed in the apparatus 600, for example, in a mode register (not shown in FIG. 6). The read latency information RL can be defined in terms of clock cycles of the CK clock signal. For example, the read latency information RL can be a number of clock cycles of the CK signal after the read command is received by the apparatus 600 when the associated read data is provided.

Write data can be supplied to the data terminals DQ, DBI, and DMI according to the WCK and WCKF clock signals. The write command may be received by the command decoder 615, which can provide internal commands to the input/output circuit 660 so that the write data can be received by data receivers in the input/output circuit 660 and supplied via the input/output circuit 660 and the read/write amplifiers 655 to the memory array 650. The write data may be written in the memory cell designated by the row address and the column address. The write data may be provided to the data terminals at a time that is defined by write latency WL information. The write latency WL information can be programmed in the apparatus 600, for example, in the mode register. The write latency WL information can be defined in terms of clock cycles of the CK clock signal. For example, the write latency information WL can be a number of clock cycles of the CK signal after the write command is received by the apparatus 600 when the associated write data is received.

The power supply terminals may be supplied with power supply potentials V_{DD} and V_{SS}. These power supply potentials V_{DD} and V_{SS} can be supplied to an internal voltage generator circuit 670. The internal voltage generator circuit 670 can generate various internal potentials V_{PP}, V_{OD}, V_{ARY}, V_{PERI}, and the like based on the power supply potentials V_{DD} and V_{SS}. The internal potential V_{PP} can be used in the row decoder 640, the internal potentials V_{OD} and V_{ARY} can be used in the sense amplifiers included in the memory array 650, and the internal potential V_{PERI} can be used in many other circuit blocks.

The power supply terminal may also be supplied with power supply potential V_{DDQ}. The power supply potential V_{DDQ} can be supplied to the input/output circuit 660 together with the power supply potential VSS. The power supply potential V_{DDQ} can be the same potential as the power supply potential V_{SS} in an embodiment of the present technology. The power supply potential V_{DDQ} can be a different potential from the power supply potential V_{DD} in another embodiment of the present technology. However, the dedicated power supply potential V_{DDQ} can be used for the input/output circuit 660 so that power supply noise generated by the input/output circuit 660 does not propagate to the other circuit blocks.

The clock terminals and data clock terminals may be supplied with external clock signals and complementary external clock signals. The external clock signals CK, CKF, WCK, WCKF can be supplied to a clock input circuit 620. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 620 can receive the external clock signals. For example, when enabled by a clock/enable signal from the command decoder 615, an input buffer can receive the clock/enable signals. The clock input circuit 620 can receive the external clock signals to generate internal clock signals ICLK. The internal clock signals ICLK can be supplied to an internal clock circuit 630. The internal clock circuit 630 can provide various phase and frequency controlled internal clock signals based on the received internal clock signals ICLK and a clock enable (not shown in FIG. 6) from the command/address input circuit 605. For example, the internal clock circuit 630 can include a clock path (not shown in FIG. 6) that receives the internal clock signal ICLK and provides various clock signals to the command decoder 615. The internal clock circuit 630 can further provide input/output (IO) clock signals. The IO clock signals can be supplied to the input/output circuit 660 and can be used as timing signals for determining output timing of read data and/or input timing of write data. The IO clock signals can be provided at multiple clock frequencies so that data can be output from and input to the apparatus 600 at different data rates. A higher clock frequency may be desirable when high memory speed is desired. A lower clock frequency may be desirable when lower power consumption is desired. The internal clock signals ICLK can also be supplied to a timing generator 635 and thus various internal clock signals can be generated.

The apparatus 600 can be connected to any one of a number of electronic devices capable of utilizing memory for the temporary or persistent storage of information, or a component thereof. For example, a host device of apparatus 600 may be a computing device such as a desktop or portable computer, a server, an enterprise device, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 600; although in other embodiments, the host device may be indirectly connected to memory device (e.g., over a networked connection or through intermediary devices).

In some embodiments, the apparatus 600 can include non-volatile memory, such as fuses or anti-fuses, configured to store predetermined information. For example, the non-volatile memory may be used to store failure/repair information, device or circuit identifiers, and/or other operational information necessary across power cycles. Such non-volatile memory may be grouped, such as for a fuse array 680, and may be at a location removed/remote from the devices or circuits that use the stored information. Accordingly, one or more of the circuits or devices described above may include local latches 682 configured to load and store the predetermined information at a closer and/or more accessible location. For illustrative purposes the local latches 682 are shown near the fuse array 680, but it is understood that the local latches 682 may be placed away from the fuse array 680 and closer to other circuits, such as a comparison circuit 684, the row decoder 640, the column decoder 645, etc. The predetermined information in the non-volatile memory (e.g., the fuse array 680) may be communicated or broadcasted at a designated time, such as after a power-on event, and the devices/circuits may load the broadcasted information or a corresponding portion thereof in the local latches 682 for local storage. The term "local" can represent proximity (e.g., within a threshold distance) between the latches and a down-stream circuit configured to access the information stored in the latches and/or inclusion within the same die.

The comparison circuit 684 can process the information in the local latches 682. As an example, the local latches 682 can store repair information used to swap defective rows/columns with redundant rows/columns (e.g., locations within local redundant memory 695 that correspond to memory cells in addition to main local memory cells/target die capacity). The comparison circuit 684 can receive addresses (e.g., row and/or column addresses) associated with incoming commands (e.g., read and/or write commands). The comparison circuit 684 can compare the receive addresses to the latched addresses to detect when the incoming commands are associated with defective cells. Based on the detection, the comparison circuit 684 and the subsequent circuits (e.g., the row decoder 640 and/or the column decoder 645) can access the local redundant memory 695 instead of the defective cells associated with the command.

The local main memory in the array 650 can be tested during chip-level tests/qualifications. Such tests/qualifications can detect the defective cells within the main memory, and replacement cells within the redundant memory 695 can be identified in response. Addresses for defective cells and/or the replacement cells can be stored in the fuse array 680. During operation, the apparatus 600 can locally and automatically access and utilize the redundant memory 695 when the address for the defective memory is identified by the controller (e.g., the memory controller, the interfacing control circuit, etc.).

The apparatus 600 can include an error processing circuit 690 coupled to the fuse array 680 and/or the local latches 682. The error processing circuit 690 can include circuitry (e.g., active and/or passive components) configured to generate error detection/correction data according to the predetermined information in the fuse array 680 (e.g., the information broadcasted to the local latches 682). The error processing circuit 690 can be further configured to receive information (e.g., the locally latched broadcast data and the corresponding error detection/correction data) from the local latches 682 and determine whether the locally latched data includes one or more errors. The error processing circuit 690 can regenerate and/or broadcast the corrected broadcast data and/or an updated error detection/correction data when the obtained local data has been corrupted.

As an illustrative example, the error processing circuit 690 can include an ECC unit configured to generate an ECC parity. The ECC unit can generate the ECC parity for each grouping of broadcast data. The ECC unit can broadcast the ECC parity after the broadcast of the corresponding grouping of the broadcast data. After the initial broadcast, the apparatus 600 can be configured to communicate the data stored in the local latches 682 back to the ECC unit. In some embodiments, the apparatus 600 can be configured to communicate the locally latched data according to a predetermined frequency/duration, operating conditions, and the like. The ECC unit can receive the locally latched data and/or the locally latched ECC parity and process the received information to determine whether the received data includes any ECC errors. The ECC unit can output the corrected information when the received data includes one or more ECC errors.

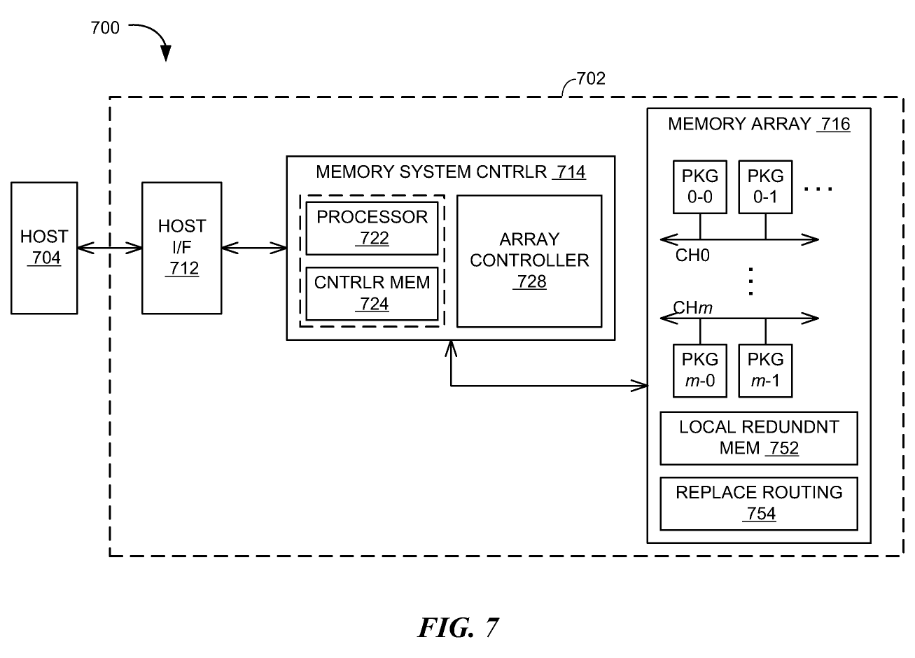

Illustrating another example of the memory devices, FIG. 7 is a block diagram of a computing system 700 having a second example memory (e.g., persistent memory, such as NAND Flash) in accordance with embodiments of the technology. The computing system 700 can include a personal computing device/system, an enterprise system, a mobile device, a server system, a database system, a distributed computing system, or the like.

The computing system 700 can have a memory system 702 coupled to a host device 704. The host device 704 can include one or more system processors that can write data to and/or read data from the memory system 702. For example, the host device 704 can include an upstream central processing unit (CPU).

The memory system 702 can include circuitry configured to store data (via, e.g., write operations) and provide access to the stored data (via, e.g., read operations). For example, the memory system 702 can include a persistent or non-volatile data storage system, such as a NAND-based Flash drive system, an SSD system, an SD card, or the like. In addition to writing and reading, the memory system 702 can erase the previously stored data. The erase operation may be used to remove data, such as in response to an erase command from the host 704, and/or as a part of moving the stored data to a different storage location (e.g., in combining data from partially written blocks into one block or in rewriting the data to a new data block to refresh).

The memory system 702 can include a host interface 712 (e.g., buffers, transmitters, receivers, and/or the like) configured to facilitate communications with the host device 704. The host interface 712 can be configured to support one or more host interconnect schemes, such as Universal Serial Bus (USB), Peripheral Component Interconnect (PCI), Serial AT Attachment (SATA), or the like. The host interface 712 can receive commands, addresses, data (e.g., write data), and/or other information from the host device 704. The host interface 712 can also send data (e.g., read data) and/or other information to the host device 704. In some embodiments, the host interface 712 can be configured to implement the UFS protocols in communicating with the host device 704.

The memory system 702 can further include a memory system controller 714 (also called a micro controller) and a memory array 716 (also called the BE). The memory array 716 can include memory cells that are configured to store a unit of information. The memory system controller 714 can be configured to control the overall operation of the memory system 702, including the operations of the memory array 716.

In one or more embodiments, the memory system 702 can correspond to the packages 200 of FIG. 2 and/or 300 of FIG. 3, the third package 400 of FIG. 4, and the memory system controller 714 can correspond to the interfacing control circuit. The memory dies (e.g., the main dies and/or the redundant dies) can correspond to the memory array 716. In other embodiments, the packages 200 of and/or 300, the third package 400 can correspond to the memory array 716, and the interfacing control circuit can correspond to control circuits local to the memory array 716 and in addition to the memory system controller 714.

In some embodiments, the memory array 716 can include a set of persistent memory (e.g., NAND) devices, packages, dies, or the like. Each of the packages can include a set of memory cells that each store data in a charge storage structure. The memory cells can include, for example, floating gate, charge trap, phase change, ferroelectric, magnetoresitive, and/or other suitable storage elements configured to store data persistently or semi-persistently. The memory cells can be one-transistor memory cells that can be programmed to a target state to represent information. For instance, electric charge can be placed on, or removed from, the charge storage structure (e.g., the charge trap or the floating gate) of the memory cell to program the cell to a particular data state. The stored charge on the charge storage structure of the memory cell can indicate the Vt of the cell. For example, a single level cell (SLC) can be programmed to a targeted one of two different data states, which can be represented by the binary units 7 or 0. Also, some flash memory cells can be programmed to a targeted one of more than two data states. Multilevel cells (MLCs) may be programmed to any one of four data states (e.g., represented by the binary 00, 01, 70, 71) to store two bits of data. Similarly, triple level cells (TLCs) may be programmed to one of eight (i.e., 2³) data states to store three bits of data, and quad level cells (QLCs) may be programmed to one of 76 (i.e., 2⁴) data states to store four bits of data.

Such memory cells may be arranged in rows (e.g., each corresponding to a word line 743) and columns (e.g., each corresponding to a bit line). The arrangements can further correspond to different groupings for the memory cells. For example, each word line can correspond to one or more memory pages. Also, the memory array 716 can include memory blocks that each include a set of memory pages. In operation, the data can be written or otherwise programmed (e.g., erased) with regards to the various memory regions of the memory array 716, such as by writing to groups of pages and/or memory blocks. In NAND-based memory, a write operation often includes programming the memory cells in selected memory pages with specific data values (e.g., a string of data bits having a value of either logic 0 or logic 7). An erase operation is similar to a write operation, except that the erase operation re-programs an entire memory block or multiple memory blocks to the same data state (e.g., logic 0).

The memory array 716 can include a set of packages, a set of dies, etc. Each of the dies can include main memory cells and die-local redundant memory 752. The main memory cells within the die can have the target die capacity, and the die-local redundant memory 752 can correspond to replacements for any defects within the main memory cells.

To utilize the die-local redundant memory 752, the memory array 716 can include replacement routing circuit 754. For example, the replacement routing circuit 754 can include persistent memory, such as fuses and/or latches, that store addresses for the defective main memory cells and/or the corresponding replacements within the die-local redundant memory 752. The replacement routing circuit 754 can further include logic or compare circuits configured to determine when an address for the defective location is replaced. The logic can internally replace the defective address with the replacement address, thereby effectuating the replacement of the defective main memory locations with the corresponding replacement locations within the die-local redundant memory 752.

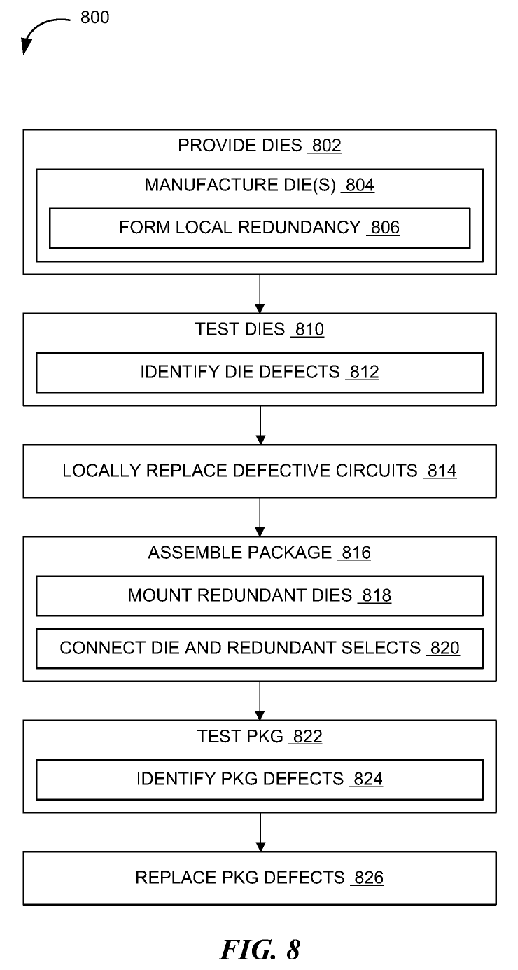

FIG. 8 is a flow diagram illustrating an example method 800 of manufacturing an apparatus (e.g., the packages 200 of FIG. 2 and/or 300 of FIG. 3, the third package 400 of FIG. 4, or a combination thereof) in accordance with an embodiment of the present technology. The method 800 can be for manufacturing and/or utilizing the replacement dies 220 of FIGS. 2, 320 of FIGS. 3, 422 and 424 of FIGS. 4, 504 of FIGS. 5A and 5B, or a combination thereof.

The method 800 can include providing dies, such as the main dies and the replacement dies, as shown at block 802. For example, the method 800 can include providing memory dies, such as the apparatus 600 of FIG. 6, the memory array 716 of FIG. 7, and/or the like. In some embodiments, providing the dies can include manufacturing the dies, such as by processing semiconductor wafers to implant dopants, form connections, and/or the like.

The provided dies can locally include replacement or redundant circuits, such as the redundant memory 695 of FIG. 6 and/or the die-local redundant memory 752 of FIG. 7. Manufacturing the dies can include forming the local redundancy, such as by including memory cells/blocks that exceed the targeted die capacity for each of the dies, as shown at block 806.

At block 810, the method 800 can include testing the individual dies. For example, known data patterns can be written to and read from the memory cells within each of the dies. Based on the accuracy of the reads, the testing process can identify defects within the dies as shown at block 812. Continuing with the memory die example, the testing process can identify the defective memory cells within the dies.

At block 814, the method 800 can include locally replacing the defective circuits. The method 800 can replace the defective circuits by storing in persistent memory the addresses or other similar identifiers of the defective circuits and the corresponding addresses of the replacement circuits in the redundancy. For example, the method 800 can include storing the defective memory cell/block identifiers and the replacement cell/block identifiers in the fuse array 680 of FIG. 6 or the replacement routing circuit 754 of FIG. 7.

At block 816, the method 800 can include assembling the package (e.g., the packages 200, 300, or 400) using the tested dies. The packages can be assembled based on mounting the main dies on a package substrate. In assembling the package, the method 800 can include mounting the redundant dies (e.g., the replacement dies 220, 320, etc.), as shown at block 818, according to a predetermined stacking scheme. The redundant dies can be mounted in addition to the main dies. Moreover, the redundant dies can be mounted at a predetermined location within the stack as described above. Additionally, the interfacing control circuit can be mounted to the package substrate.

Also for the assembly, the method 800 can include connecting the dies. For example, the mounted dies can be connected using bondwires according to the group wiring scheme 500 of FIG. 5A. Further, the method 800 can include connecting die and redundant select connections. The provided/manufactured dies can have the die-selection connections 552 of FIG. 5B along with the redundant-select connections 554 of FIG. 5B. Accordingly, the method 800 can include forming connections, such as using bondwires, between the die-selection connections 552 and the redundant-select connections 554 on each of the mounted dies to their respective corresponding locations/connectors on the package substrate. Thus, the method 800 can include completing signal paths for the die/chip select signals and the redundant-select signals between the interfacing control circuit and the mounted dies.

After the package assembly, the method 800 can include testing the assembled package as shown at block 822. Similar to the die test, the package test may test the functional circuitry within each of the mounted dies within the package. The package test can identify the package defects in the functional circuitry, as shown at block 824. For example, known data patterns can be written to and read from available addresses within each of the memory dies within the package. The package test can identify the defects (e.g., defective memory addresses) based on the accuracy of the read back.

In response to detecting the defects at the package level, the method 800 can include replacing the package defect using the replacement dies as shown at block 826. In some embodiments, the replacement can occur in direct response to detecting package-level defects and/or when the aggregate of the defects across the dies yields a corresponding capacity that is less than the targeted package capacity. In replacing the package defects, the defective die identifier and/or the defective location within such die can be stored in the interfacing control circuit. In some embodiments, the local addresses (e.g., addresses or location identifiers within the dies) of the replacement circuit within the replacement die can be match with that of the defective circuit. Accordingly, the replacement may be implemented by accessing the same address in a different/replacement die.

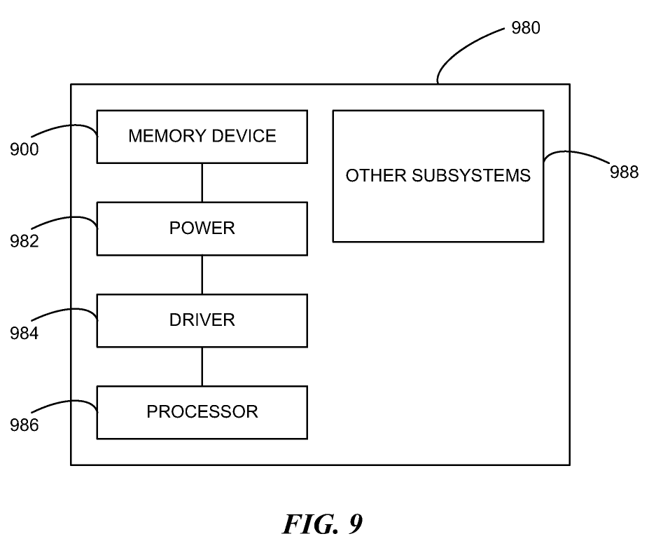

FIG. 9 is a schematic view of a system that includes an apparatus in accordance with embodiments of the present technology. Any one of the semiconductor devices described above with reference to FIGS. 2-8 can be incorporated into any of a myriad of larger and/or more complex systems, a representative example of which is system 990 shown schematically in FIG. 9. The system 990 can include a semiconductor device 900 ("device 900") (e.g., a semiconductor device, package, and/or assembly), a power source 992, a driver 994, a processor 996, and/or other subsystems or components 998. The device 900 can include features generally similar to those devices described above. The resulting system 990 can perform any of a wide variety of functions, such as memory storage, data processing, and/or other suitable functions. Accordingly, representative systems 990 can include, without limitation, hand-held devices (e.g., mobile phones, tablets, digital readers, and digital audio players), computers, and appliances. Components of the system 990 may be housed in a single unit or distributed over multiple, interconnected units (e.g., through a communications network). The components of the system 990 can also include remote devices and any of a wide variety of computer-readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Throughout this disclosure, the singular terms "a," "an," and "the" include plural referents unless the context clearly indicates otherwise. Similarly, unless the word "or" is expressly limited to mean only a single item exclusive from the other items in reference to a list of two or more items, then the use of "or" in such a list is to be interpreted as including (a) any single item in the list, (b) all of the items in the list, or (c) any combination of the items in the list. Additionally, the terms "comprising," "including," and "having" are used throughout to mean including at least the recited feature(s) such that any greater number of the same feature and/or additional types of other features are not precluded. Reference herein to "one embodiment," "an embodiment," "some embodiments" or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

What is claimed is:

1. A semiconductor package, comprising:
a package substrate;
at least one die stack mounted on the package substrate and including:
n number of main dies mounted over the package substrate, wherein the n number of main dies are configured to provide a targeted package capacity for data storage at the semiconductor package, and
at least one replacement die for providing additional memory capacity in excess of the targeted package capacity and configured to selectively replace bad memory cells in the n number of main dies to retain the targeted package capacity for the semiconductor package; and
at least one control circuitry mounted on the package substrate and coupled to the at least one die stack, the at least one control circuitry configured to control interface with the n number of main dies and the at least one replacement die.

2. The semiconductor package of claim 1, wherein:
the n number of main dies and the at least one replacement die include memory cells arranged in memory blocks;
the bad memory cells correspond to one or more defective memory blocks; and
the at least one replacement die includes one or more replacement memory blocks that each uniquely replace one of the defective memory blocks.

3. The semiconductor package of claim 2, wherein:
each of the n number of main dies includes (1) main memory having a targeted die capacity for data storage and (2) redundant memory in excess of the targeted die capacity; and
the targeted package capacity corresponds to a combination of the targeted die capacity and a quantity n of the main dies.

4. The semiconductor package of claim 1, wherein the n number of main dies includes 16 dies or more.

5. The semiconductor package of claim 4, wherein:
the n number of main dies includes memory circuits arranged according to m number of channels; and
the at least one replacement die includes one replacement die configured to replace memory circuits for one of the m number of channels.

6. The semiconductor package of claim 5, wherein the at least one replacement die includes m number of replacement dies that are each configured to replace memory circuits for a unique one of the m number of channels.

7. The semiconductor package of claim 5, wherein the n number of main dies and the at least one replacement die include NAND Flash memory circuits.

8. The semiconductor package of claim 5, wherein:
the semiconductor package is configured to store data according to a data unit having a first segment and a second segment; and
the at least one die stack includes two or more die stacks with each stack including:
one or more first main dies corresponding to the first segment of the data unit;
one or more second main dies corresponding to the second segment of the data unit;
a first replacement die corresponding to the first segment of the data unit; and
a second replacement die corresponding to the second segment of the data unit.

9. The semiconductor package of claim 8, wherein:
the n number of main dies and the at least one replacement die include Dynamic Random Access Memory (DRAM) circuits;
the first segment corresponds to an upper segment of the data unit; and
the second segment corresponds to a lower segment of the data unit.

10. The semiconductor package of claim 1, wherein:
each of the n number of main dies includes a die-select connection configured to receive a die-select signal from the at least one control circuitry for uniquely selecting a corresponding one of the n number of main dies; and
the at least one replacement die includes (1) a die-select connection is commonly connected to the die-select connection of one of the n number of main dies and (2) a redundant-select connection configured to receive a redundant-select signal from the at least one control circuitry for selecting the at least one replacement die.

11. The semiconductor package of claim 1, wherein the at least one replacement die is located at under or on top of the n number of main dies.

12. The semiconductor package of claim 1, wherein:
the n number of main dies at least a first grouping of dies and a second grouping of dies;
the at least one die stack includes one die stack including:
the first grouping of dies mounted successively offset along a first lateral direction according to a cascaded arrangement;
the at least one replacement die includes one replacement die attached over the first grouping of dies; and
the second grouping of dies mounted successively offset along a second lateral direction according to the cascade arrangement and over the one replacement die.

13. The semiconductor package of claim 1, wherein:
the n number of main dies at least a first grouping of dies and a second grouping of dies;
the at least one die stack includes two die stack including:
a first die stack having the first grouping of dies mounted successively offset along a first lateral direction;
the at least one replacement die includes one replacement die attached over or disposed between the first grouping of dies; and
a second die stack having the second grouping of dies mounted successively offset along a second lateral direction.

14. The semiconductor package of claim 1, wherein the semiconductor package is an enterprise data storage device.

15. An enterprise memory package, comprising:
a package substrate; and
a die stack having two or more main dies and a replacement die,
wherein each die of the two or more main dies and the replacement die includes (1) local main memory having a targeted die capacity for data storage and (2) local redundant memory in excess of the targeted die capacity and configured to replace defective circuits in the local main memory,
wherein the enterprise memory package has a package capacity for data storage based on the target die capacity of the main dies and separate from the local redundant memory and separate from the replacement die, and
wherein the replacement die is configured to replace defects in the main dies that are discovered after assembly of the die stack.

16. The enterprise memory package of claim 15, wherein the enterprise memory package includes 16 main dies and one replacement die.

17. The enterprise memory package of claim 15, wherein the enterprise memory package includes 16 main dies and two replacement dies.

18. The enterprise memory package of claim 15, wherein:
the die stack is one of four die stacks; and
each of the four die stacks includes four main dies and two replacement dies.

19. A method of manufacturing an apparatus, the method comprising:
forming a die stack based on mounting two or more main dies and a replacement die on a package substrate;
testing the die stack to identify defective circuits therein; and
replacing the defective circuits using circuitry within the replacement die.

20. The method of claim 19, wherein:
the two or more main dies and the replacement die are memory devices that each include main memory and redundant memory;
the defective circuits identified by testing the die stack correspond to a second set of defects;
further comprising:
individually testing the memory devices to identify a first set of defects within one or more of the memory devices; and
replacing the first set of defects with the redundant memory local to one or more corresponding dies having the first set of defects, wherein the first set of defects are replaced before the memory devices are mounted on the package substrate.
